(19) United States
(12) Patent Application Publication
(10) Pub. No.: US 2009/0033215 A1
(43) Pub. Date: Feb. 5, 2009

(54) ORGANIC EL DISPLAY APPARATUS

(75) Inventors: TOMONARI HORIKIRI, Sagamihara-shi (JP); TAKURO YAMAZAKI, Kawasaki-shi (JP); MASAHIRO TANAKA, Chiba-shi (JP); MASATO ITO, Mobara-shi (JP)

Correspondence Address: FITZPATRICK CELLA HARPER & SCINTO, 30 ROCKEFELLER PLAZA, NEW YORK, NY, 10112, US

(73) Assignees: CANON KABUSHIKI KAISHA, TOKYO (JP); HITACHI DISPLAYS LTD., Mobara-shi (JP)

(21) Appl. No.: 12/184,001

(22) Filed: Jul. 31, 2008

(30) Foreign Application Priority Data
Aug. 2, 2007 (JP) 2007-201986

(51) Int. Cl. H01L 51/54

(52) U.S. Cl. 313/504

(57) ABSTRACT

Provided is an organic EL display apparatus which can prevent, moisture in a planarizing film or outside moisture intruding into the planarizing film, from intruding into a light-emitting portion through a cracked portion of an insulating film, thereby suppressing peripheral degradation. The organic EL display apparatus includes a substrate, an insulating film formed on the substrate and having a plurality of openings at equal intervals, and a plurality of organic EL devices formed in the openings on the substrate and each constituting a light-emitting portion, in which the organic EL layer is formed on an inner side than the opening located at an outermost periphery, and in which in the opening located at an outer periphery of the organic EL layer, a layer which is the same as the first electrode and the second electrode are in contact with each other.

### BACKGROUND OF THE INVENTION

1. Field of the Invention

The present invention relates to an organic EL display apparatus used for a flat panel display and the like.

2. Description of the Related Art

In recent years, as a flat panel display, an organic EL display apparatus using an organic electroluminescence (hereinafter simply referred to as “organic EL”) device which is a self-emission type device has been attracting attention. A common organic EL display apparatus is shown in FIG. 8.

The organic EL display apparatus includes an insulating film 805 disposed at the periphery of respective openings for the purpose of separating the organic EL devices constituting respective light-emitting portions from one another, and an insulating film (hereinafter, referred to as “planarizing film”) 803 for planarizing unevenness due to TFT circuits 802 formed on a substrate 801. The organic EL device includes a first electrode 804 patterned for each of the light-emitting portions, an organic EL layer 806 formed on the first electrode 804, and a second electrode 807 formed on the organic EL layer 806 continuously extending over the respective light-emitting portions. Incidentally, in the figure, reference numeral 808 denotes a cover glass, reference numeral 809 a sealing agent, reference numeral 810 a crack generated in the insulating film, reference numeral 811 moisture outside of the device, and reference numeral 812 moisture contained in the organic material of the planarizing film.

In the organic EL display apparatus as configured above, the organic EL layer 806 interposed between the electrodes emits light by flowing a current between the first electrode 804 and the second electrode 807. As the material of the insulating film 805, an organic material such as polyimide and acrylic resins and an inorganic material such as silicon nitride and silicon oxide are used. Further, for the planarizing film 803, a material excellent in planarizing property, for example, an acryl resin as an organic material is mainly used.

Meanwhile, it is known that the display characteristics of the organic EL device tend to be degraded due to moisture and oxygen. As an example of such degradation, there is caused a phenomenon (hereinafter, referred to as “peripheral degradation”) in which the luminance is reduced at an edge of an opening in an outermost peripheral light-emitting portion. The cause of the peripheral degradation is considered that moisture contained in the insulating film or planarizing film formed of an organic material intrudes into the light-emitting portion through the insulating film, thereby generating the degradation. Particularly, outside of the outermost peripheral light-emitting portion, the insulating film and the planarizing film are disposed extending outside the organic EL device, which results in increase of the moisture content or intrusion of outside moisture (see 811 in FIG. 8), so that the peripheral degradation easily occurs.

Therefore, in order to solve the problem of the peripheral degradation, in Japanese Patent Application Laid-Open No. 2005-302707, a configuration has been proposed in which an edge portion of a first electrode and a non-water permeable planarizing film are covered by a bank (corresponding to the insulating film in the present invention), and the bank has formed an opening extending around an outer periphery of a light-emitting portion and the side wall and bottom surface of the opening are covered by a second electrode.

Further, in Japanese Patent Application Laid-Open No. 2006-58751, a configuration has been proposed in which a planarizing film has a groove portion formed in such a manner as to separate pixel metal electrodes of adjacent pixels from each other.

However, the present inventors have found that the technology disclosed in the above-mentioned patent documents cannot sufficiently prevent the intrusion of moisture contained in a planarizing film into a light-emitting portion and the intrusion of outside moisture into the light-emitting portion through an insulating film.

An insulating film has openings in the parts where light-emitting portions are formed, and the openings are disposed at equal intervals. However, the openings formed at equal intervals in a display region are not formed outside the display region, which generates a discontinuous portion in the pattern of the insulating film. To this discontinuous portion, that is, a boundary portion where an unevenness pattern of the insulating film and the pattern of the openings vary, a residual stress due to heat history in a heating/cooling process such as dehydration or an external stress is concentrated, so that the insulating film is liable to be cracked (see 810 in FIG. 8). Through the cracked portion of the insulating film, moisture (see 812 in FIG. 8) contained in an organic material (for example, acrylic resin) of a planarizing film or outside moisture (see 811 in FIG. 8) intruding into the planarizing film further intrudes into a light-emitting portion, thereby also generating peripheral degradation.

As described above, in the organic EL display apparatus, it is important to resolve the problem that moisture intrudes into a light-emitting portion through an insulating film or a planarizing film. Further, it has been found that the problem becomes particularly prominent when the insulating film is formed of an inorganic material.

With respect to this problem, according to Japanese Patent Application Laid-Open No. 2005-302707, the cross-sectional shape of the bank at the periphery of the opening is different from the cross-sectional shape of the bank in the light-emitting portion, and the openings are not disposed at equal intervals. In this case, the dispersion of the stress of the bank becomes uneven, so that the bank at the periphery of the opening constituting the light-emitting portion is liable to be cracked. Therefore, there is a possibility that moisture may intrude into the light-emitting portion though the cracked portion, thereby causing peripheral degradation.

According to Japanese Patent Application Laid-Open No. 2006-58751, the planarizing film is formed in such a manner as to separate the pixel metal electrodes from each other. However, since the planarizing film is provided adjacent the insulating film, it is difficult to resolve the problem that moisture in the planarizing film intrudes into the light-emitting portion through a cracked portion of the insulating film.

### SUMMARY OF THE INVENTION

It is, therefore, an object of the present invention to provide an organic EL display apparatus which can prevent, moisture in a planarizing film or outside moisture intruding into the planarizing film, from intruding into a light-emitting portion through a cracked portion of an insulating film, thereby suppressing peripheral degradation.

According to the present invention, there is provided an organic EL display apparatus, which includes: a substrate; an insulating film formed on the substrate and having a plurality of openings at equal intervals; and a plurality of organic EL devices formed in the openings on the substrate and each constituting a light-emitting portion, the organic EL devices each including a first electrode patterned for each of the light-emitting portions; an organic EL layer formed on the first electrode; and a second electrode formed continuously on the organic EL layer so as to extend over the light-emitting portions, an edge portion of the first electrode being covered by the insulating film, in which the organic EL layer is formed on an inner side than the opening located at an outermost periphery, and in which in the opening located at an outer periphery of the organic EL layer, a layer which is the same as the first electrode and the second electrode are in contact with each other.

According to the present invention, moisture in a planarizing film or outside moisture intruding into the planarizing film can be prevented from intruding into a light-emitting portion through a cracked portion of an insulating film, thereby suppressing peripheral degradation.

Further features of the present invention will become apparent from the following description of exemplary embodiments with reference to the accompanying drawings.

### BRIEF DESCRIPTION OF THE DRAWINGS

FIG. 1 is a schematic cross-sectional view illustrating an embodiment of the organic EL display apparatus of the present invention.

FIG. 2 is a schematic view of the embodiment of the organic EL display apparatus of the present invention as seen in a direction perpendicular to a display surface.

FIG. 3 is a partially enlarged schematic view of an embodiment of the organic EL display apparatus of the present invention as seen in a direction perpendicular to a display surface.

FIG. 4 is a partially enlarged schematic view of an embodiment of the organic EL display apparatus of the present invention as seen in a direction perpendicular to a display surface.

FIG. 5 is a partially enlarged schematic view of an embodiment of the organic EL display apparatus of the present invention as seen in a direction perpendicular to a display surface.

FIG. 6 is a partially enlarged schematic view of an embodiment of the organic EL display apparatus of the present invention as seen in a direction perpendicular to a display surface.

FIG. 7 is a partially enlarged schematic view of an embodiment of the organic EL display apparatus of the present invention as seen in a direction perpendicular to a display surface.

FIG. 8 is a schematic cross-sectional view of an example of a conventional organic EL display apparatus.

### DESCRIPTION OF THE EMBODIMENTS

Hereinafter, embodiments of an organic EL display apparatus according to the present invention will be described.

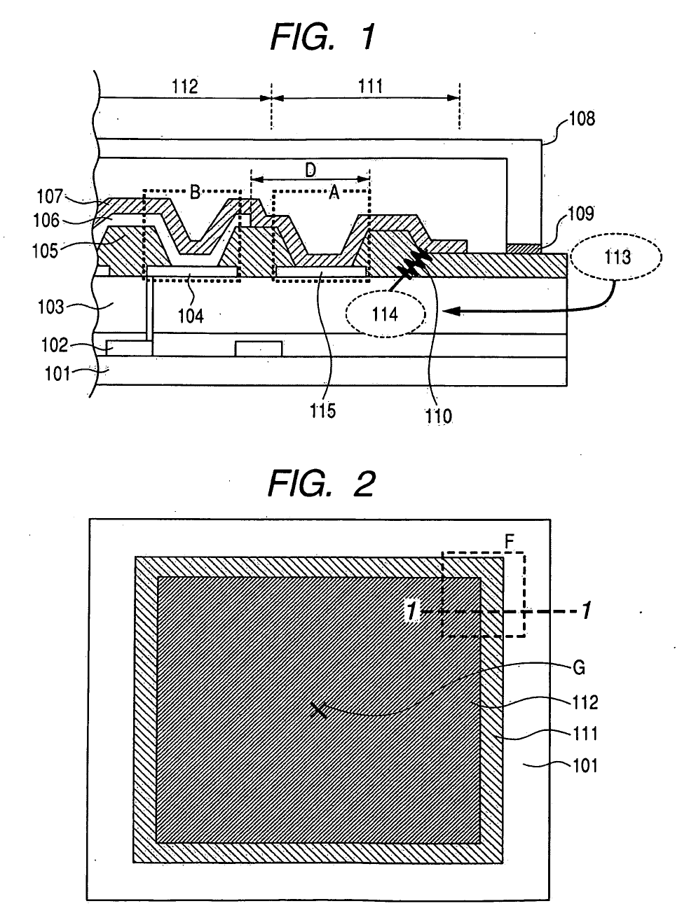

FIG. 1 is a partial cross-sectional view schematically illustrating an organic EL display of the present invention. FIG. 2 is a schematic view of the organic EL display apparatus of the present invention as seen in a direction perpendicular to a display surface. Incidentally, FIG. 1 is a cross section taken along line 1-1 of FIG. 2.

As shown in the figures, in the organic EL display apparatus, there are formed a light-emitting region 112 having pixels (light-emitting portions; however, dummy pixels described later do not emit light) arranged at equal intervals, and a non-light-emitting region 111 at the outer periphery thereof.

That is, TFT circuits 102 are formed on a glass substrate 101, and a planarizing film 103 is stacked thereon to planarize unevenness formed by provision of the TFT circuits 102. At respective pixel positions on the planarizing film 103 are patterned first electrodes 104, and further, layers 115 which are each the same as the first electrode are also patterned at the outer periphery of the first electrodes 104 in accordance with the arrangement of the first electrodes 104. At this time, it is desirable that the first electrode 104 and the layer 115 which is the same as the first electrode (hereinafter, sometimes simply referred to as “identical layer”) are of the same material because of easiness in production steps.

Further, an insulating film 105 is formed so as to cover edge portions of the first electrodes 104 and the identical layers 115 and also to separate the first electrodes 104 and the identical layers 115. As a result, openings B each having the first electrode 104 exposed therein are formed in the light-emitting region 112, and openings A each having the identical layer 115 exposed therein are formed in the non-light-emitting region 111.

Here, the positional relationship in the display surface is described using relative expression with a center G of the display surface being defined as a base point. Therefore, the term “opening at outer periphery” herein employed refers to a group of openings (surrounding openings) and an individual opening which are located outside the display region as seen from the center G of the light-emitting region 112. Further, the term “outermost peripheral opening” herein employed refers to a group of openings (surrounding openings) and an individual opening which are located most distant from the center G of the light-emitting region 112 within a predetermined area.

It is desirable that the shape of the opening A of the non-light-emitting region 111 is the same as the shape of the opening B of the light-emitting region 112. In other words, it is desirable that all the openings have the same shape. The reason is that when the insulating film 105 is formed using an inorganic material, in a case where the shape of the opening A is different from that of the opening B, the insulating film 105 is liable to be cracked at a boundary between the parts with the different opening shapes due to nonuniformity of the stress of the inorganic material, which is not desirable.

As the material of the insulating film 105, either of an organic material or inorganic material may be used. As the organic material, polyimide and acrylic resins can be used. As the inorganic material, silicon nitride, silicon oxide, and the like can be used. The inorganic material is preferably used as the insulating film 105 because of having low moisture content and low moisture permeability.

In order to use the region including the openings B and the region (insulating film 105) between the openings B as the light-emitting region 112, the organic EL layer 106 is formed only in the light-emitting region 112. That is, the organic EL layer 106 is formed at least on an inner side than the outermost peripheral opening A.

The organic EL layer 106, because of easiness of film deposition steps, is preferably continuously formed entirely over the light-emitting region 112, that is, extending over all the light-emitting portions. Further, it is desirable that a distance D between an edge on the outer peripheral opening A side of the organic EL layer 106 and an outside edge of the opening A is 100 μm or more. When the distance D is 100 μm or more, an effect of suppressing diffusion (or penetration) of moisture is increased.

Incidentally, while the organic EL layer 106 may include a hole injection layer, a hole-transporting layer, an organic light-emitting layer, an electron-transporting layer, an electron injection layer and the like, the organic EL layer 106 needs to include at least an organic light-emitting layer. The materials used for forming these layers may be hitherto known materials and are not particularly limited.

On the organic EL layer 106 of the light-emitting region 112, and on the identical layers 115 exposed in the openings A and the insulating film 105 of the non-light-emitting region 111, a second electrode 107 is formed. As a result, the organic EL display apparatus has a configuration such that in the opening A at the outer periphery of the organic EL layer 106, the identical layer 115 is in contact with the second electrode 107 and further in contact with the planarizing film 103 and with the insulating film 105. However, although it is indispensable that the edge portion of the first electrode 104 is covered by the insulating film 105, the edge portion of the identical layer 115 need not necessarily be covered by the insulating film 105.

In the organic EL display apparatus of the above described configuration, the organic EL layer 106 which could become a diffusion (or penetration) path of moisture is not formed in the region where peripheral degradation may be generated. Therefore, moisture 114 contained in the planarizing film 103 and outside moisture 113 intruding into the insulating film 105 (when the insulating film is of an organic resin) are prevented from directly intruding further into the organic EL layer 106 of the light-emitting region 112. Further, moisture 114 in the planarizing film 103 intruding through a crack 110 of the insulating film 105 of the non-light-emitting region 111 (when the insulating film is of an inorganic material) is prevented from directly intruding further into the organic EL layer 106 of the light-emitting region 112.

As described above, it is desirable that the identical layer 115 is made of the same material as that of the first electrode 104, and the materials of the identical layer 115 and the second electrode 107 are not particularly limited as long as they do not affect the device characteristics. However, a transparent conductive oxide is preferably employed because of having an effect of highly suppressing diffusion of moisture at the boundary at which the identical layer 115 and the second electrode 107 are in contact with each other. In particular, ITO, ITZO or IZO is preferable. Further, when a transparent conductive oxide is selected as the second electrode 107, and an inorganic material is selected as the insulating film 105, the effect of suppressing diffusion of moisture becomes high also at the boundary at which the second electrode 107 and the insulating film 105 are in contact with each other.

That is, between the outside edge portion of the opening A and the edge portion of the organic EL layer 106, at the two boundaries including one between the identical layer 115 and the second electrode 107 and one between the second electrode 107 and the insulating film 105, it is possible to suppress the transfer of the moisture. As a result, the peripheral degradation can be suppressed more effectively. Particularly, in the organic EL display apparatus of the present embodiment, the above described configuration according to the present invention is applied to the four sides of the display surface, so that the peripheral degradation of the organic EL display apparatus can be suppressed.

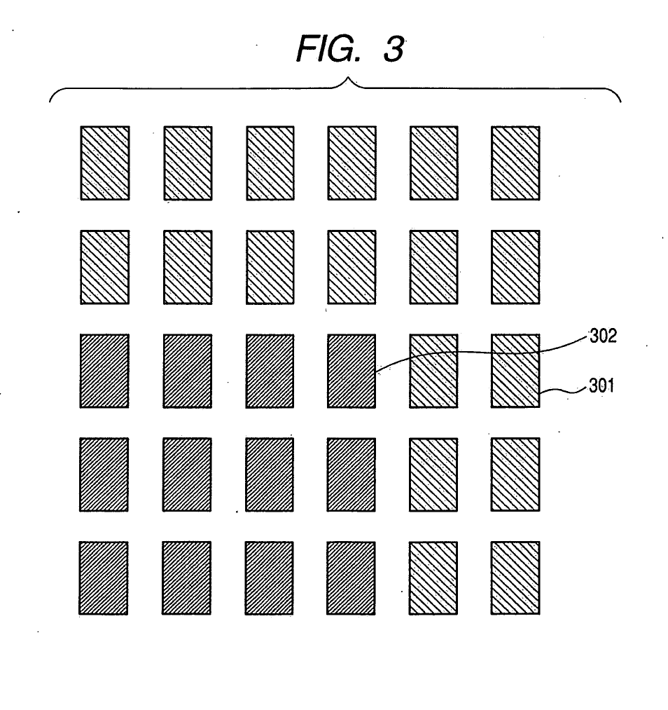

Next, out of the openings A located at the outer periphery of the organic EL layer 106, concerning the openings in which the identical layer 115 and the second electrode 107 are in contact with each other, the layout thereof at the display surface will be described with reference to FIGS. 3 to 7.

FIGS. 3 to 7 are enlarged views of the corner portion of the display surface of the organic EL display apparatus according to the present invention (corresponding to, for example, F in FIG. 2; however, the configuration of openings being different from that of FIG. 2).

In FIG. 3, reference numeral 302 denotes openings of the light-emitting portion in each of which the organic EL layer 106 and the second electrode 107 are formed on the first electrode 104, and reference numeral 301 denotes openings located at the outer periphery of the organic EL layer 106 in each of which the identical layer 115 and the second electrode 107 are in contact with each other. In the example shown in FIG. 3, the plurality of openings including ones at the outermost periphery and ones on the inner side thereof are disposed, that is, at the outer periphery of the light-emitting region having the openings 302 formed therein, the openings 301 in which the identical layer 115 and the second electrode 107 are in contact with each other are disposed doubly. Therefore, the peripheral degradation of the organic EL display apparatus can be suppressed more reliably.

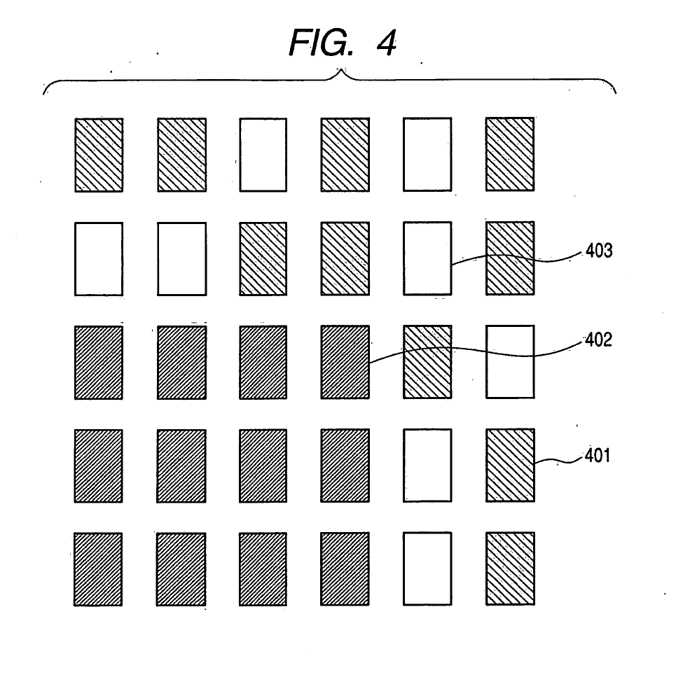

In an example shown in FIG. 4, at the outer periphery of openings 402 of the light-emitting portions in each of which the organic EL layer 106 and the second electrode 107 are formed on the first electrode 104, openings 401 in each of which the identical layer 115 and the second electrode 107 are in contact with each other are disposed. Further, openings 403 in each of which only the identical layer 115 is formed are disposed. The second electrode 107 is formed also in the openings 401 and 402 while extending over the insulating films located at the periphery of the openings. Even in this layout, the transfer of moisture to the openings 402 of the light-emitting portions can be suppressed, thereby suppressing peripheral degradation.

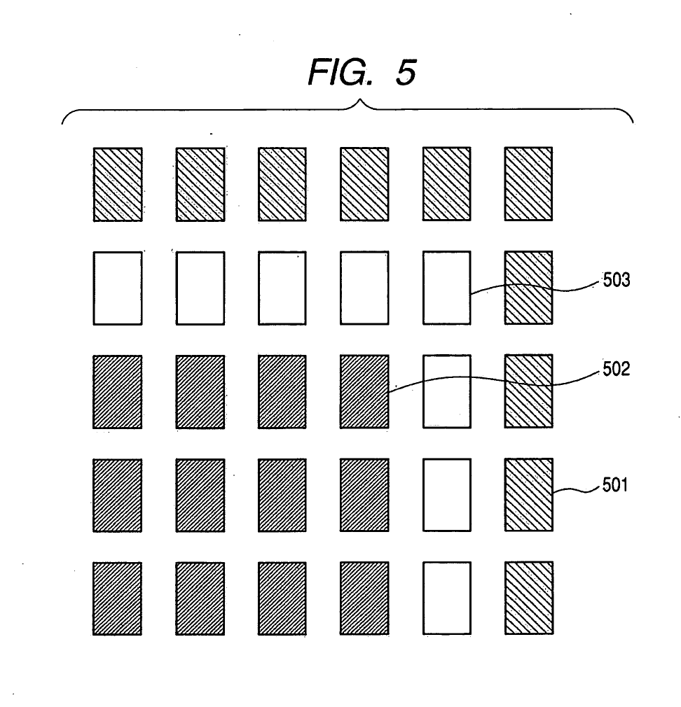

In an example shown in FIG. 5, openings 503 in each of which only the identical layer 115 is formed are disposed at the outer periphery of openings 502 of the light-emitting portions in each of which the organic EL layer 106 and the second electrode 107 are formed on the first electrode 104. Moreover, at the further outer periphery thereof, openings 501 in each of which the identical layer 115 and the second electrode 107 are in contact with each other are disposed. The second electrode 107 is formed also in the openings 501 and 502 while extending over the insulating films located at the periphery of the openings. Even in this layout, the transfer of moisture to the openings 503 of the light-emitting portions can be suppressed, thereby suppressing peripheral degradation.

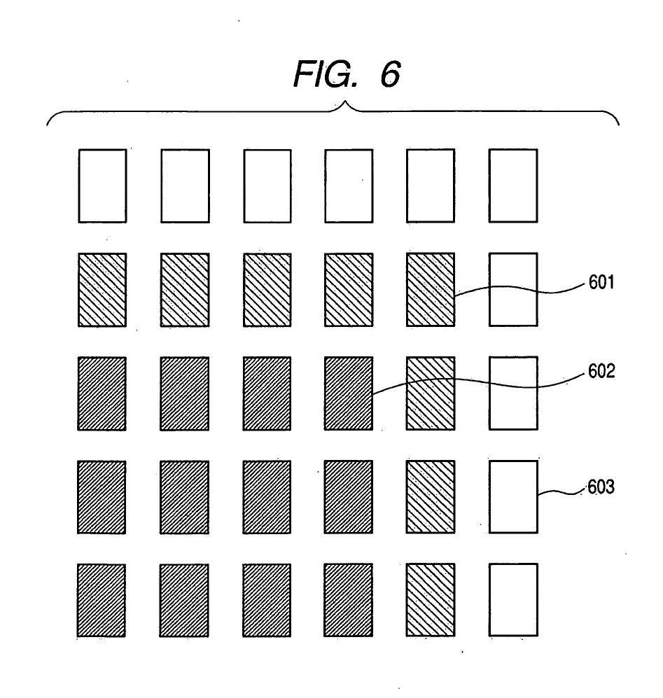

In an example shown in FIG. 6, openings 601 in each of which the identical layer 115 and the second electrode 107 are in contact with each other are disposed at the outer periphery of openings 602 of the light-emitting portions in each of which the organic EL layer 106 and the second electrode 107 are formed on the first electrode 104. Further, at the further outer periphery, openings 603 in each of which the only identical layer 115 is formed are disposed. Even in this layout, the transfer of moisture to the openings 602 of the light-emitting portions can be suppressed, thereby suppressing the peripheral degradation. In FIG. 6, the openings located at the outer periphery of the light-emitting portions have the arrangement of two rows by two columns. However, when there are more rows and more columns available, it is sufficient that outer peripheral openings of at least one row by one column other than the outermost peripheral openings are covered.

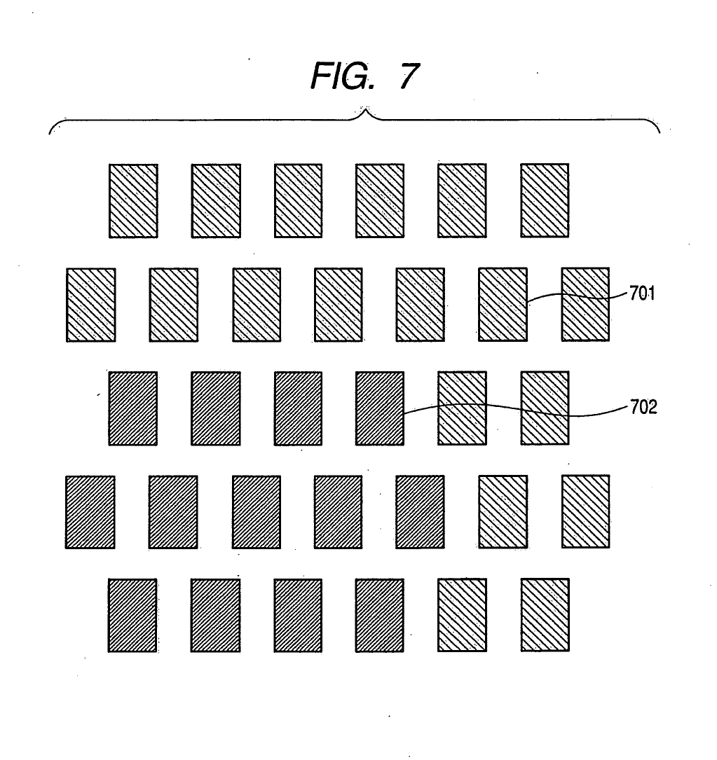

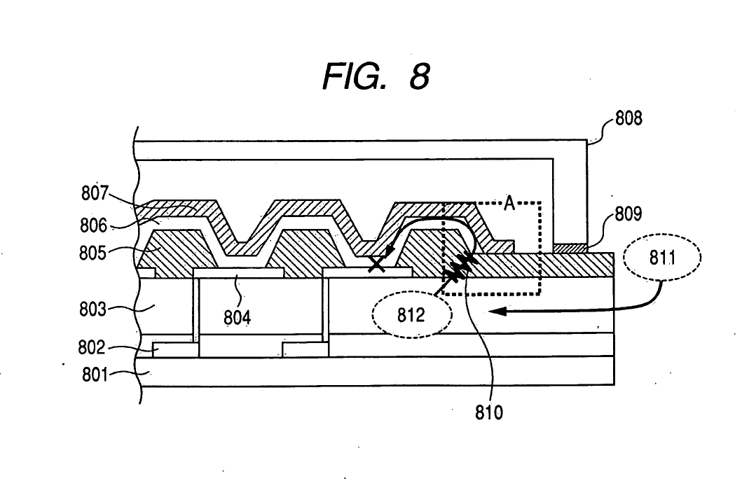

In FIG. 7, reference numeral 702 denotes openings 702 of the light-emitting portions in each of which the organic EL layer 106 and the second electrode 107 are formed on the first electrode 104, and reference numeral 701 denotes openings 701 in each of which the identical layer 115 and the second electrode 107 are in contact with each other disposed at the outer periphery of the organic EL layer 106. The light-emitting portions shown in FIG. 7 are disposed in an arrangement different from that of the light-emitting portions shown in FIGS. 1 to 6, and the light-emitting portions adjacent to each other in the vertical direction in the drawing are offset by ½ pitch with respect to each other. Such an arrangement is employed for attaining the so-called delta arrangement.

In FIGS. 1 and 3 to 7, the examples of the openings at the outer periphery of the light-emitting region are depicted as having an arrangement of one row by one line or an arrangement of two rows by two lines. However, the number and arrangement pattern of the openings at the outer periphery of the light-emitting region in the present invention are not limited thereto. Further, although the shape and disposal of the openings are depicted in a rectangular stripe shape, it is only necessary for the openings to be disposed at equal intervals, and a polygonal shape such as a honeycomb shape and a circular shape can be adopted in the present invention.

The EL display apparatus of the present invention may have light-emitting pixels each composed of a light-emitting portion for emitting red light, a light-emitting portion for emitting green light, and a light-emitting portion for emitting blue light. By constituting one pixel of light-emitting portions of three light colors for red light emission, green light emission, and blue light emission, and by disposing a plurality of such pixels, a display apparatus capable of full color display can be provided.

In the organic EL display apparatus of the present invention, a dummy pixel may be formed at the outer periphery of the light-emitting region 112. When the dummy pixel is used, the identical layer 115 of the dummy pixel and the second electrode 107 are brought into contact with each other.

The term “dummy pixel” herein employed refers to a structure which has a layer 115 being the same as a first electrode and having the same pattern as the first electrode 104 or has the opening A having the same pattern as the opening B and which is not effective for display.

In general, the dummy pixel is disposed, in many cases, at the outermost periphery of the effective display region (corresponding to light-emitting region in the present invention). The reason is that since there is a possibility that the display characteristics of pixels located at the outermost periphery of the light-emitting region may become unstable due to production process (specifically, the TFT circuit 102, the first electrode 104, and the like may not be formed as intended), pixels with unstable display characteristics need to be removed from the light-emitting region. In the present invention, by bringing the identical layer 115 of the dummy pixel and the second electrode 107 into contact with each other, peripheral degradation can be suppressed without further providing a new region for bringing the identical layer 115 and the second electrode 107 into contact with each other.

The organic EL display apparatus can be classified into a bottom emission system and a top emission system depending on the difference of the arrangement of the TFT circuits. In the present invention, the both systems can be adopted. Further, a drive system such as an active matrix drive system or a simple matrix drive system can be adopted.

### EXAMPLES

Hereinafter, examples of the present invention will be described.

### Example 1

An organic EL display apparatus of the present invention having a structure illustrated in FIGS. 1 and 2 was produced.

TFT circuits 102 were formed on a glass substrate 101, and as a protection layer for the TFT circuits 102, a thin film of silicon nitride was formed by a CVD method. Next, an acrylic negative resist was coated on the TFT substrate and was pre-baked, and after that, was exposed through a photomask so that through-holes were formed only in a light-emitting region 112. The substrate was immersed in an etchant to beu subjected to development, and was subjected to post-baking to form a planarizing film 103.

Next, aluminum (Al) was evaporated by sputtering by using a metal mask so as to have a thickness of 200 nm such that first electrodes 104 and identical layers 115 were disposed at equal intervals on a light-emitting region 112 and on a non-light-emitting region 111. This TFT substrate was heated for four hours at 200° C. at a vacuum degree of 10⁻⁵ Pa to perform dehydration.

After the completion of the dehydration step, silicon nitride (SiN) was deposited by a CVD method using a metal mask so as to cover edge portions of the first electrodes 104 of the light-emitting region 112 and the identical layers 115 of the non-light-emitting region 111, thereby forming an insulating film 105 made of silicon nitride as an inorganic material. The shape of the insulating film 105 was made the same for both the non-light-emitting region 111 and the light-emitting region 112.

Next, in the light-emitting region 112 having the openings B, at a vacuum degree of 10⁻⁵ Pa, a hole-transporting layer, an organic light-emitting layer (green color), an electron-transporting layer, and an electron injection layer were stacked on the first electrode 104 in the mentioned order thereby forming an organic EL layer 106. Further, a second electrode 107 of 60 nm in thickness made of IZO was formed by sputtering thereon so as to cover the light-emitting region 112 and the non-light-emitting region 111. After that, the periphery was coated with an UV curable sealing agent 109, and further, a cover glass 108 having a drying agent coated on the inner periphery thereof for absorbing moisture was bonded to the TFT substrate. Then, the UV curable sealing agent 109 was irradiated with ultraviolet light for six minutes to be ultraviolet cured, thereby producing the organic EL display apparatus.

In the present example, since the first electrode 104 is made of Al, the identical layer 105 is also made of Al, and the second electrode 107 is made of IZO. Further, the distance D between the edge on the outer peripheral opening A side of the organic EL layer 106 and the outside edge of the opening A was 200 μm.

The thus obtained organic EL display apparatus was allowed to stand in a constant temperature testing equipment of 80° C. and a humidity of 30%, and was taken out after every passage of a predetermined time period and allowed to emit light, thereby confirming peripheral degradation. As a result, at the outermost periphery of the display surface, peripheral degradation was confirmed to be generated after passage of 1500 hours.

### Example 2

An organic EL display apparatus was produced by following the same procedure as in Example 1 with the exception that ITO was evaporated in a thickness of 100 nm by sputtering so as to cover the aluminum which was the first electrode in Example 1, and the ITO film was used as a first electrode.

The thus obtained organic EL display apparatus was allowed to stand in a constant temperature testing equipment of 80° C. and a humidity of 30%, and was taken out after every passage of a predetermined time period and allowed to emit light, thereby confirming peripheral degradation. As a result, at the outermost periphery of the display surface, peripheral degradation was not confirmed even after passage of 3000 hours.

### Example 3

An organic EL display apparatus was produced by following the same procedure as in Example 1 with the exception that IZO was evaporated in a thickness of 100 nm by sputtering so as to cover the aluminum which was the first electrode in Example 1, and the IZO film was used as a first electrode.

The thus obtained organic EL display apparatus was allowed to stand in a constant temperature testing equipment of 80° C. and a humidity of 30%, and was taken out after every passage of a predetermined time period and allowed to emit light, thereby confirming peripheral degradation. As a result, at the outermost periphery of the display surface, peripheral degradation was not confirmed even after passage of 3000 hours.

### Comparative Example 1

An organic EL display apparatus was produced by following the same procedure as in Example 2 with the exception that the organic EL layer was deposited extending over the openings located at the outermost periphery, i.e., the organic EL layer was deposited on the entire region including both the light-emitting region 112 and the non-light-emitting region 111.

The thus obtained organic EL display apparatus was allowed to stand in a constant temperature testing equipment of 80° C. and a humidity of 30%, and was taken out after every passage of a predetermined time period and allowed to emit light, thereby confirming peripheral degradation. Since this Comparative Example 1 was not an organic EL display apparatus utilizing the present invention, peripheral degradation was confirmed to be generated after passage of 300 hours at the outermost periphery of the display surface.

### Examples 4, 5, 6 and 7

Organic EL display apparatuses were produced by following the same procedure as in Example 2 with the exception that distance D between the edge on the outer peripheral opening side of the organic EL layer and the outside edge of the opening was set to 50 μm, 100 μm, 300 μm, and 500 μm, respectively.

Each of the thus obtained organic EL display apparatuses was allowed to stand in a constant temperature testing equipment of 80° C. and a humidity of 30%, and was taken out after every passage of a predetermined time period and allowed to emit light, thereby confirming peripheral degradation. The results are shown in Table 1.

### Example 8

An organic EL display apparatus was produced by following the same procedure as in Example 2 with the exception that the insulating film was formed of polyimide, not silicon nitride.

The thus obtained organic EL display apparatus was allowed to stand in a constant temperature testing equipment of 80° C. and a humidity of 30%, and was taken out after every passage of a predetermined time period and allowed to emit light, thereby confirming peripheral degradation. As a result, at the outer periphery of the light-emitting region, peripheral degradation was confirmed to be generated after passage of 1000 hours.

### Example 9

An organic EL display apparatus was produced by following the same procedure as in Example 2 with the exception that the layout in the display surface of the openings in each of which the identical layer and the second electrode were in contact with each other was changed to that shown in FIG. 3.

The thus obtained organic EL display apparatus was allowed to stand in a constant temperature testing equipment of 80° C. and a humidity of 30%, and was taken out after every passage of a predetermined time period and allowed to emit light, thereby confirming peripheral degradation. As a result, at the outer periphery of the light-emitting region, peripheral degradation was not confirmed even after passage of 3000 hours.

### Example 10

An organic EL display apparatus was produced by following the same procedure as in Example 2 with the exception that the layout in the display surface of the openings in each of which the identical layer and the second electrode were in contact with each other was changed to that shown in FIG. 5.

The thus obtained organic EL display apparatus was allowed to stand in a constant temperature testing equipment of 80° C. and a humidity of 30%, and was taken out after every passage of a predetermined time period and allowed to emit light, thereby confirming peripheral degradation. As a result, at the outer periphery of the light-emitting region, peripheral degradation was not confirmed even after passage of 3000 hours.

### Example 11

An organic EL display apparatus was produced by following the same procedure as in Example 2 with the exception that the layout in the display surface of the openings in each of which the identical layer and the second electrode were in contact with each other was changed to that shown in FIG. 6.

The thus obtained organic EL display apparatus was allowed to stand in a constant temperature testing equipment of 80° C. and a humidity of 30%, and was taken out after every passage of a predetermined time period and allowed to emit light, thereby confirming peripheral degradation. As a result, at the outer periphery of the light-emitting region, peripheral degradation was not confirmed even after passage of 3000 hours.

### Example 12

The same procedure as in Example 2 up to and including the step of forming the organic EL layer was followed. Next, at a vacuum degree of 10⁻⁵ Pa, a hole-transporting layer was evaporated on the first electrode, and by using a metal mask for shielding a portion other than a red-light-emitting portion, the red-light-emitting layer was evaporated. Subsequently, by using a metal mask for shielding a portion other than a green-light-emitting portion, the green-light-emitting layer was evaporated. Finally, by using a metal mask for shielding a portion other than a blue-light-emitting portion, the blue-light-emitting layer was evaporated. After that, an electron-transporting layer and an electron injection layer were stacked thereon in the mentioned order. Further, a second electrode of 200 nm in thickness made of IZO was formed by sputtering thereon so as to cover the region having the openings 301 and 302 formed therein illustrated in FIG. 3. After that, the periphery was coated with an UV curable sealing agent, and further, a cover glass having a drying agent coated on the inner periphery thereof for absorbing moisture was bonded to the TFT substrate. Then, the UV curable sealing agent was irradiated with ultraviolet light for six minutes to be ultraviolet cured, thereby producing the organic EL display apparatus.

The thus obtained organic EL display apparatus was allowed to stand in a constant temperature testing equipment of 80° C. and a humidity of 30%, and was taken out after every passage of a predetermined time period and allowed to emit light, thereby confirming peripheral degradation. As a result, at the outer periphery of the light-emitting region, peripheral degradation was not confirmed even after passage of 3000 hours.

TABLE 1

| | | | | | Time until |
|---|---|---|---|---|---|
| | | | | | Generation |
| | | | | | of |
| | | | | | Peripheral |
| | Insulating | Identical | Second | Distance* | Degradation |
| | Film | Layer | Electrode | (μm) | (hours) |
| Ex. 1 | SiN | Al | IZO | 200 | 1500 |
| Ex. 2 | SiN | ITO | IZO | 200 | over 3000 |
| Ex. 3 | SiN | IZO | IZO | 200 | over 3000 |
| Ex. 4 | SiN | ITO | IZO | 50 | 700 |
| Ex. 5 | SiN | ITO | IZO | 100 | 2000 |
| Ex. 6 | SiN | ITO | IZO | 300 | over 3000 |
| Ex. 7 | SiN | ITO | IZO | 500 | over 3000 |
| Ex. 8 | PI | ITO | IZO | 200 | 1000 |
| Comp. | SiN | ITO | IZO | 0 | 300 |
| Ex. 1 | | | | | |

Note:
“Distance*” refers to the distance between the edge on the outer peripheral opening side of the organic EL layer and the outside edge of the outer peripheral opening according to the present invention.

By producing an organic EL display apparatus driven by an active matrix system or the like according to the present invention, an EL display product is provided which can be driven stably for a longer period of time and is higher in performance.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2007-201986, filed Aug. 2, 2007, which is hereby incorporated by reference herein in its entirety.

What is claimed is:

1. An organic EL display apparatus, comprising:
a substrate;
an insulating film formed on the substrate and having a plurality of openings at equal intervals; and
a plurality of organic EL devices formed in the openings on the substrate and each constituting a light-emitting portion, the organic EL devices each comprising a first electrode patterned for each of the light-emitting portions; an organic EL layer formed on the first electrode; and a second electrode formed continuously on the organic EL layer so as to extend over the light-emitting portions, an edge portion of the first electrode being covered by the insulating film,
wherein the organic EL layer is formed on an inner side than the opening located at an outermost periphery, and wherein in the opening located at an outer periphery of the organic EL layer, a layer which is the same as the first electrode and the second electrode are in contact with each other.

2. The organic EL display apparatus according to claim 1, wherein the organic EL layer is formed continuously extending over the light-emitting portions.

3. The organic EL display apparatus according to claim 1, wherein the shapes of all the openings are the same.

4. The organic EL display apparatus according to claim 1, wherein in a plurality of the openings located at the outermost periphery and on an inner side thereof, the identical layer and the second electrode are in contact with each other, and the organic EL layer is formed on an inner side than the plurality of the openings.

5. The organic EL display apparatus according to claim 1, wherein the insulating film comprises silicon nitride.

6. The organic EL display apparatus according to claim 1, wherein the identical layer and the second electrode each comprise ITO or IZO.

7. The organic EL display apparatus according to claim 1, wherein a distance between an edge on the outer peripheral opening side of the organic EL layer and an outside edge of the opening is 100 μm or more.

8. The organic EL display apparatus according to claim 1, comprising a light-emitting pixel comprising the light-emitting portion for emitting red light, the light-emitting portion for emitting green light, and the light-emitting portion for emitting blue light.
